(19) United States
(12) Patent Application Publication
(10) Pub. No.: US 2018/0138867 A1
(43) Pub. Date: May 17, 2018

(54) BASE STATION AND DISTORTION COMPENSATION METHOD

(71) Applicant: FUJITSU LIMITED, Kawasaki-shi (JP)

(72) Inventors: Yasuhiro OKAWA, Sendai (JP); Junichi SUGAWARA, Sendai (JP); Youji NAKATA, Sapporo (JP); Hirotake HONDA, Sendai (JP)

(73) Assignee: FUJITSU LIMITED, Kawasaki-shi (JP)

(21) Appl. No.: 15/783,751

(22) Filed: Oct. 13, 2017

(30) Foreign Application Priority Data
Nov. 11, 2016 (JP) 2016-221026

(51) Int. Cl. H03F 1/32; H04B 1/04; H04B 15/00

(52) U.S. Cl. CPC H03F 1/3241; H04B 2001/0425; H04B 15/005; H04B 1/0475

(57) ABSTRACT

There is provided a base station including a memory, a processor coupled to the memory and the processor configured to generate a distortion-compensated transmission signal, and a plurality of transmitters, a transmitter of the plurality of transmitters configured to include a first amplifier configured to amplify the distortion-compensated transmission signal so as to transmit the distortion-compensated transmission signal, and an attenuator configured to attenuate a feedback signal generated by splitting the distortion-compensated transmission signal amplified by the first amplifier so as to feed back the feedback signal to the processor, wherein the processor is further configured to perform distortion compensation according to a distortion compensation coefficient based on a power of the feedback signal.

### CROSS-REFERENCE TO RELATED APPLICATION

This application is based upon and claims the benefit of priority of the prior Japanese Patent Application No. 2016-221026, filed on Nov. 11, 2016, the entire contents of which are incorporated herein by reference.

### FIELD

The embodiments discussed herein are related to base stations and distortion compensation methods.

### BACKGROUND

In recent years, at a previous stage of a high-output amplifier mounted on a base station, a distortion compensating unit is provided. In the distortion compensating unit, a transmission signal inputted to an amplifier is multiplied by a predetermined distortion compensation coefficient, thereby providing the transmission signal with a characteristic opposite to the nonlinear characteristic of the amplifier. The transmission signal multiplied by the distortion compensation coefficient is then inputted to and amplified by the amplifier. An output from the amplifier is fed back via a distributor. Based on the fed-back signal, the distortion compensation coefficient by which the transmission signal inputted to the amplifier is multiplied is updated so that distortion components included in the output from the amplifier are small. This reduces the distortion components included in the output from the amplifier.

Japanese Laid-open Patent Publication No. 2006-157385 is an example of related art.

### SUMMARY

According to an aspect of the invention, a base station includes a memory, a processor coupled to the memory and the processor configured to generate a distortion-compensated transmission signal, and a plurality of transmitters, a transmitter of the plurality of transmitters configured to include a first amplifier configured to amplify the distortion-compensated transmission signal so as to transmit the distortion-compensated transmission signal, and an attenuator configured to attenuate a feedback signal generated by splitting the distortion-compensated transmission signal amplified by the first amplifier so as to feed back the feedback signal to the processor, wherein the processor is further configured to perform distortion compensation according to a distortion compensation coefficient based on a power of the feedback signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of an example of a base station in a first embodiment;

FIG. 2 is a diagram of an example of an attenuation table;

FIG. 3A and FIG. 3B are diagrams each depicting an example of a frequency spectrum of a signal flowing through a feedback route;

FIG. 4A and FIG. 4B are diagrams each depicting an example of the frequency spectrum of the signal flowing through the feedback route;

FIG. 5A to FIG. 5H are timing diagrams of an example of timing of update process in the first embodiment;

FIG. 6 is a flowchart of an example of attenuation table generation process;

FIG. 7 is a flowchart of an example of update process in the first embodiment;

FIG. 8 is a block diagram of an example of a base station in a second embodiment;

FIG. 9A to FIG. 9H are timing diagrams of an example of timing of update process in the second embodiment;

FIG. 10 is a flowchart of an example of update process in the second embodiment;

FIG. 11 is a block diagram of an example of a base station in a third embodiment;

FIG. 12A and FIG. 12B are diagrams each depicting an example of a frequency spectrum of a signal flowing through a feedback route;

FIG. 13A to FIG. 13D are timing diagrams of an example of timing of update process in the third embodiment;

FIG. 14 is a flowchart of an example of update process in the third embodiment;

FIG. 15 is a block diagram of an example of a base station in a fourth embodiment;

FIG. 16A to FIG. 16E are timing diagrams of an example of timing of update process in the fourth embodiment; and

FIG. 17 is a diagram of an example of hardware of the base station.

### DESCRIPTION OF EMBODIMENTS

In recent years, with an increase in traffic, the number of base stations and devices installed in the base stations is increasing. However, places for installations of the base stations are limited, and thus the functions of a plurality of base stations may be consolidated in one base station or device. When the functions of a plurality of base stations are consolidated in one base station, signal wirings may be adjacently disposed, and a signal flowing through one signal wiring may cause an interference signal on another signal wiring.

For example, when signal wirings where a feedback signal for performing distortion compensation of an amplifier is transmitted are adjacently disposed among transmitters which transmit separate transmission signals, a feedback signal flowing through one signal wiring causes an interference signal on another signal wiring. With this, not only a signal fed back from an output from the amplifier as a distortion compensation target but also the interference signal occurring due to a signal fed back from an output from another amplifier is inputted to a distortion compensating unit. The distortion compensating unit updates a distortion compensation coefficient based on these signals. The interference signal fluctuates irrespective of the distortion compensation coefficient adjusted for the amplifier as a distortion compensation target. Thus, it is difficult for the distortion compensating unit to calculate a distortion compensation coefficient for decreasing distortion components included in the output signal for the amplifier as a distortion compensation target. This degrades distortion compensation performance of the distortion compensating unit.

In the following, embodiments of technology capable of inhibiting degradation in distortion compensation performance are described in detail based on the drawings. The following embodiments do not limit the disclosed technology.

### First Embodiment

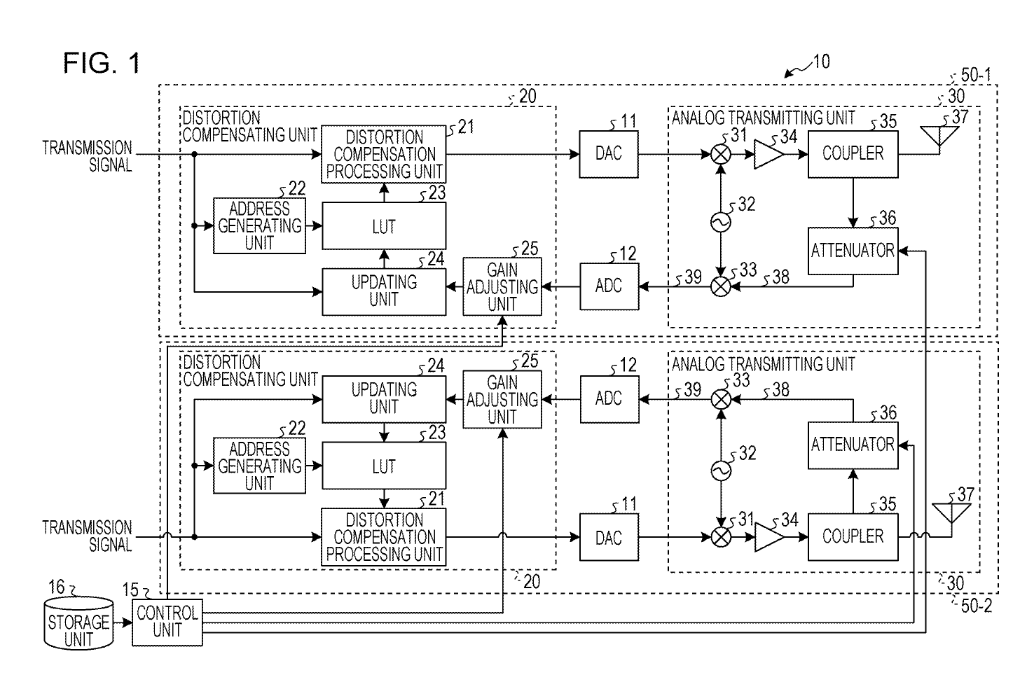

FIG. 1 is a block diagram of an example of a base station 10 in a first embodiment. The base station 10 in the present embodiment has a control unit 15, a storage unit 16, and a plurality of transmitters 50-1 and 50-2. In the specification, the transmitter 50-1 is referred to as a branch A, and the transmitter 50-2 is referred to as a branch B. Also in the following, the plurality of transmitter s 50-1 and 50-2 are collectively and simply referred to as a transmitter 50 when not distinguished from each other. While the base station 10 has two branches in the present embodiment, the base station 10 may have three or more branches in another example.

Each transmitter 50 has a digital to analog converter (DAC) 11, an analog to digital converter (ADC) 12, a distortion compensating unit 20, and an analog transmitting unit 30.

The distortion compensating unit 20 performs distortion compensation based on a distortion compensation coefficient calculated based on a signal fed back via a feedback route, which will be described further below. For example, by performing arithmetic operation on a transmission signal based on the distortion compensation coefficient for providing the transmission signal with a characteristic opposite to the nonlinear characteristic of an amplifier included in the analog transmitting unit 30, the distortion compensating unit 20 performs distortion compensation of the amplifier. The distortion compensating unit 20 then outputs the transmission signal subjected to distortion compensation to the DAC 11. The DAC 11 converts the transmission signal outputted from the distortion compensating unit 20 from a digital signal to an analog signal.

The analog transmitting unit 30 performs a predetermined process such as up-conversion or amplification on the transmission signal converted by the DAC 11 to the analog signal, and wirelessly transmits the processed transmission signal. Also, the analog transmitting unit 30 attenuates part of an output from the amplifier included in the analog transmitting unit 30 by a predetermined attenuation, and then performs a process such as down-conversion. The analog transmitting unit 30 then outputs the processed signal as a feedback signal to the ADC 12. The ADC 12 converts the feedback signal outputted from the analog transmitting unit 30 from an analog signal to a digital signal. The distortion compensating unit 20 updates the distortion compensation coefficient for use in arithmetic operation of distortion compensation based on the feedback signal converted by the ADC 12 to the digital signal.

In the present embodiment, the distortion compensating unit 20 in each transmitter 50 has a distortion compensation processing unit 21, an address generating unit 22, a look up table (LUT) 23, an updating unit 24, and a gain adjusting unit 25.

The address generating unit 22 generates an address in accordance with the power of the transmission signal. The LUT 23 retains a distortion compensation coefficient in association with an address, and outputs the distortion compensation coefficient corresponding to the address generated by the address generating unit 22 to the distortion compensation processing unit 21. The distortion compensation processing unit 21 performs a predetermined arithmetic operation on the transmission signal by using the distortion compensation coefficient outputted from the LUT 23, thereby performing distortion compensation to provide the transmission signal with a characteristic opposite to the nonlinear characteristic of the amplifier in the analog transmitting unit 30. For example, by multiplying the transmission signal by the distortion compensation coefficient outputted from the LUT 23, the distortion compensation processing unit 21 provides the transmission signal with a characteristic opposite to the nonlinear characteristic of the amplifier in the analog transmitting unit 30. The distortion compensation processing unit 21 then outputs the transmission signal subjected to distortion compensation to the DAC 11.

The gain adjusting unit 25 adjusts a gain of the feedback signal by amplifying the power of the feedback signal outputted from the ADC 12 in accordance with an adjustment amount of the gain indicated by the control unit 15. The gain when the gain adjusting unit 25 amplifies the feedback signal is approximately equal to an attenuation of an attenuator 36, which will be described further below. The gain adjusting unit 25 is an example of a second amplifier. The updating unit 24 calculates a distortion compensation coefficient based on the transmission signal inputted to the transmitter 50 and the feedback signal with the gain adjusted by the gain adjusting unit 25. The updating unit 24 then updates the distortion compensation coefficient in the LUT 23 with the calculated distortion compensation coefficient. The updating unit 24 is an example of a calculating unit.

Each analog transmitting unit 30 has an up-converter 31, an oscillator 32, a down-converter 33, a power amplifier (PA) 34, a coupler 35, the attenuator 36, and an antenna 37. The up-converter 31 performs a process such as up-conversion or modulation on the transmission signal outputted from the DAC 11 based on a local oscillation signal generated by the oscillator 32. The PA 34 amplifies and outputs the transmission signal subjected to the process such as up-conversion by the up-converter 31. The PA 34 is an example of a first amplifier. The antenna 37 emits the transmission signal amplified by the PA 34 as a wireless signal to space.

The coupler 35 outputs part of the transmission signal amplified by the PA 34 to the attenuator 36 as a feedback signal. The attenuator 36 attenuates the feedback signal outputted from the coupler 35 by an attenuation indicated by the control unit 15. The attenuator 36 then outputs the attenuated feedback signal to the down-converter 33 via a wiring 38. Based on the local oscillation signal generated by the oscillator 32, the down-converter 33 performs a process such as down-conversion or demodulation on the feedback signal outputted from the attenuator 36. The feedback signal subjected to the process such as down-conversion by the down-converter 33 is outputted to the ADC 12 via a wiring 39. The attenuator 36, the wiring 38, and the wiring 39 are examples of a feedback route. That is, the feedback route attenuates an output from the PA 34 and feeds back a signal of the attenuated output.

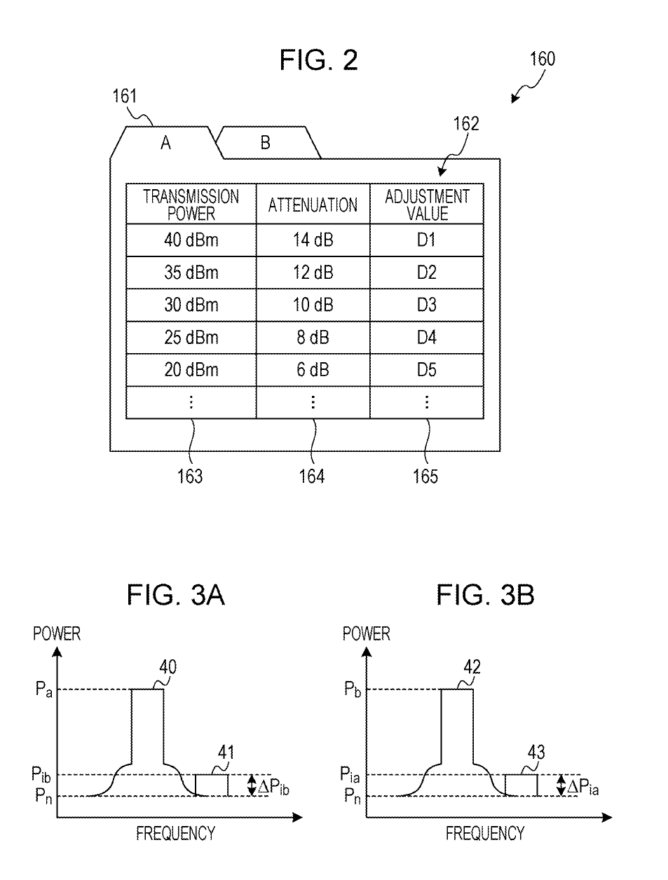

The storage unit 16 stores an attenuation table 160, for example, depicted in FIG. 2. FIG. 2 is a diagram of an example of the attenuation table 160. The attenuation table 160 has individual tables 162 in association with identifiers 161 for identifying the respective branches. Each individual table 162 stores attenuations 164 to be set to the attenuator 36 and gain adjustment values 165 to be set to the gain adjusting unit 25, in association with transmission powers 163.

The control unit 15 monitors the power of the transmission signal transmitted in each branch. With reference to the attenuation table 160 in the storage unit 16 for each branch, the control unit 15 acquires an attenuation and an adjustment value corresponding to the transmission power. The control unit 15 then sets the acquired attenuation to the attenuator 36 and sets the acquired adjustment value to the gain adjusting unit 25, for each branch.

In the attenuation table 160 illustrated in FIG. 2, transmission power values stored in the individual table 162 of each branch are discrete values. Thus, when acquiring an attenuation and an adjustment value for each branch, the control unit 15 specifies a value closest to current transmission power among the transmission power values stored in the individual table 162 and larger than the current transmission power. The control unit 15 then acquires an attenuation and an adjustment value in association with the specified transmission power value.

Here, with the plurality of transmitters 50 adjacently disposed in the base station 10 by, for example, reducing the size of the base station 10, for example, the wiring 38 and the wiring 39 in each branch may be disposed as being adjacent to the wiring 38 and the wiring 39 in another branch. In this case, by the feedback signal flowing through the wiring 38 and the wiring 39 in one analog transmitting unit 30, an interference signal may occur on the wiring 38 and the wiring 39 in another analog transmitting unit 30, for example, as depicted in FIG. 3A and FIG. 3B. FIG. 3A and FIG. 3B are diagrams each depicting an example of a frequency spectrum of a signal flowing through a feedback route. FIG. 3A depicts an example of the frequency spectrum of the signal flowing through the wiring 38 in the branch A, and FIG. 3B depicts an example of the frequency spectrum of the signal flowing through the wiring 38 in the branch B. FIG. 3A and FIG. 3B each depict an example of the frequency spectrum of the signal flowing through the wiring 38 when the attenuation of the attenuator 36 in each branch is 0.

For example, as depicted in FIG. 3A, an interference signal 41 occurs on the wiring 38 in the branch A by a feedback signal 40 outputted from the coupler 35 and also a feedback signal outputted from the coupler 35 in the branch B and flowing through the wiring 38 in the branch B. Here, for example, as depicted in FIG. 3A, on the wiring 38 in the branch A, the power of the feedback signal 40 is defined as Pₐ, the power of the interference signal 41 is defined as P_{ib}, and the power of a noise floor present on the wiring 38 in the branch A is defined as Pₙ. Also, for example, as depicted in FIG. 3A, a power difference between the power P_{ib} of the interference signal 41 and the noise floor Pₙ is defined as ΔP_{ib}.

Also, for example, as depicted in FIG. 3B, an interference signal 43 occurs on the wiring 38 in the branch B by a feedback signal 42 outputted from the coupler 35 and also the feedback signal 40 flowing through the wiring 38 in the branch A. Here, for example, as depicted in FIG. 3B, on the wiring 38 in the branch B, the power of the feedback signal 42 is defined as P_{b}, the power of the interference signal 43 is defined as Pᵢₐ, and the power of a noise floor present on the wiring 38 in the branch B is defined as Pₙ. Also, for example, as depicted in FIG. 3B, a power difference between the power Pᵢₐ of the interference signal 43 and the noise floor Pₙ is defined as ΔPᵢₐ.

On the wiring 38 in the branch A, for example, as depicted in FIG. 3A, the feedback signal 40 and also the interference signal 41 flow. The feedback signal 40 and the interference signal 41 flowing through the wiring 38 are then inputted to the distortion compensating unit 20 via the down-converter 33, the wiring 39, and the ADC 12. Here, if the updating unit 24 of the distortion compensating unit 20 updates a distortion compensation coefficient in the LUT 23 based on the feedback signal 40, distortion of the PA 34 in the analog transmitting unit 30 may be accurately compensated for by updating the distortion compensation coefficient in the LUT 23. However, the signal outputted from the analog transmitting unit 30 includes the feedback signal 40 as well as the interference signal 41. Thus, when the distortion compensation coefficient in the LUT 23 is updated based on the signal including the feedback signal 40 and the interference signal 41, it is difficult to accurately compensate for distortion of the PA 34 in the analog transmitting unit 30. This situation similarly applies also to the branch B.

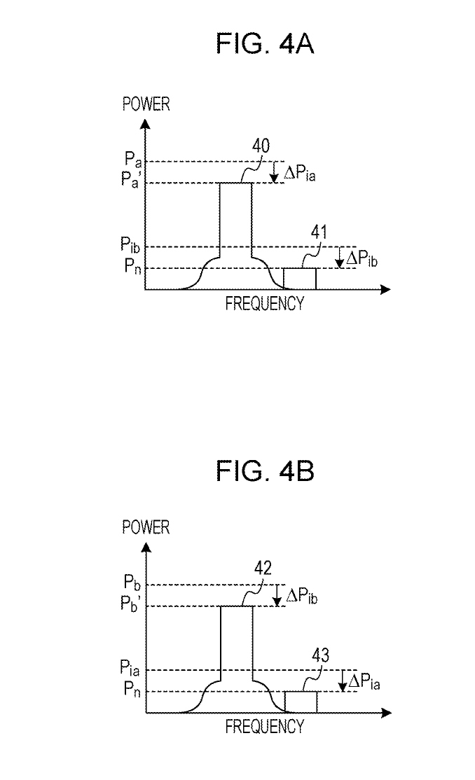

Here, a relation between an attenuation set in the attenuator 36 and a gain adjustment value set in the gain adjusting unit 25 in each branch is described by using FIG. 4A and FIG. 4B. FIG. 4A and FIG. 4B are diagrams each depicting an example of the frequency spectrum of the signal flowing through the feedback route. FIG. 4A depicts an example of the frequency spectrum of the signal flowing through the wiring 38 in the branch A, and FIG. 4B depicts an example of the frequency spectrum of the signal flowing through the wiring 38 in the branch B.

For example, as depicted in FIG. 4A, the attenuator 36 in the branch A attenuates the feedback signal 40 outputted from the coupler 35 by a predetermined attenuation. In the present embodiment, for example, as depicted in FIG. 4B, the attenuator 36 in the branch A attenuates the feedback signal 40 by an attenuation corresponding to the power difference ΔPᵢₐ between the power Pᵢₐ of the interference signal 43 and the noise floor Pₙ. This reduces the power of the interference signal 43 by ΔPᵢₐ, for example, as depicted in FIG. 4B, the interference signal 43 occurring on the wiring 38 in the branch B by the feedback signal 40 flowing through the wiring 38 in the branch A. This causes the power of the interference signal 43 occurring on the wiring 38 in the branch B to be equal to or smaller than the noise floor Pₙ. This allows the attenuator 36 in the branch A to reduce the power of the interference signal 43 occurring on the wiring 38 in the branch B and inhibit degradation in accuracy of distortion compensation in the branch B.

Similarly, for example, as depicted in FIG. 4B, the attenuator 36 in the branch B attenuates the feedback signal 42 outputted from the coupler 35 by a predetermined attenuation. In the present embodiment, for example, as depicted in FIG. 4A, the attenuator 36 in the branch B attenuates the feedback signal 42 by an attenuation corresponding to the power difference ΔP_{ib} between the power P_{ib} of the interference signal 41 and the noise floor Pₙ. This reduces the power of the interference signal 41 by ΔP_{ib}, for example, as depicted in FIG. 4A, the interference signal 41 occurring on the wiring 38 in the branch A by the feedback signal 42 flowing through the wiring 38 in the branch B. This causes the power of the interference signal 41 occurring on the wiring 38 in the branch A to be equal to or smaller than the noise floor Pₙ. This allows the attenuator 36 in the branch B to reduce the power of the interference signal 41 occurring on the wiring 38 in the branch A and inhibit degradation in accuracy of distortion compensation in the branch A.

If the attenuation of the feedback signal is increased, the attenuator 36 in each branch may reduce the power of the interference signal occurring on the wiring 38 in another branch, thereby more improving accuracy of distortion compensation in the other branch. However, if the attenuation of the feedback signal is increased too much, the power of the feedback signal becomes too low, and accuracy of distortion compensation performed by using the feedback signal may be degraded. Thus, the attenuation of the attenuator 36 in each branch preferably corresponds to a power difference between the power of the interference signal occurring on the wiring 38 in the other branch by the feedback signal of the relevant branch and the noise floor Pₙ.

As described above, in the base station 10 of the present embodiment, the feedback signal outputted from the coupler 35 is attenuated by the attenuator 36 in each branch. This reduces the power of the feedback signal flowing through the wiring 38 and the wiring 39 in each branch, and also reduces the power of the interference signal occurring on the wiring 38 and the wiring 39 in the other branch. This reduces the power of the interference signal included in the signal fed back to the distortion compensating unit 20 in each branch. The updating unit 24 in each branch then updates the distortion compensation coefficient in the LUT 23 based on the signal with the reduced interference signal. This allows the distortion compensating unit 20 to accurately compensate for distortion of the PA 34.

Also, the gain adjusting unit 25 in each branch amplifies the power of the signal fed back to the distortion compensating unit 20 by a power approximately equal to the power attenuated by the attenuator 36. This makes the power of the feedback signal outputted from the coupler 35 and the power of the feedback signal inputted to the updating unit 24 approximately equal to each other in each branch. This decreases a deviation of the power of the feedback signal inputted to the updating unit 24 and allows the distortion compensating unit 20 to accurately compensate for distortion of the PA 34 in the analog transmitting unit 30.

Also in the present embodiment, the control unit 15 determines an attenuation and an adjustment value in each branch based on the transmission power. This allows the control unit 15 to keep the power of the interference signal occurring on the feedback route in each branch at a predetermined power (for example, the power of the noise floor) or lower. This allows the control unit 15 to inhibit degradation in accuracy of distortion compensation in the base station 10.

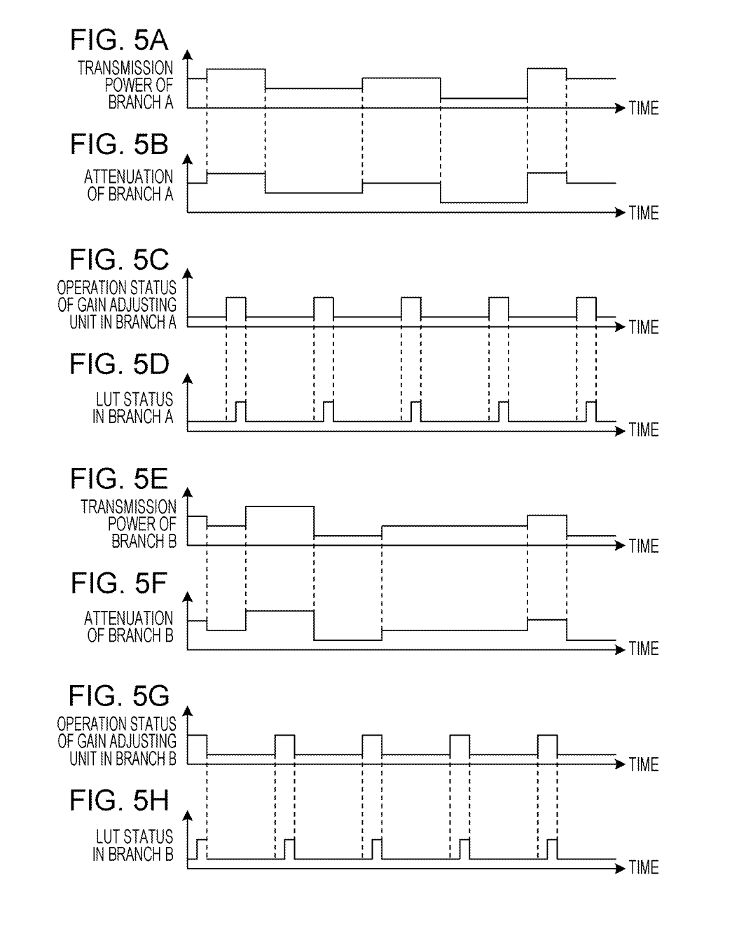

FIG. 5A to FIG. 5H are timing diagrams of an example of timing of update process in the first embodiment. When the transmission power of the branch A is changed, for example, as depicted in FIG. 5A, the control unit 15 acquires an attenuation and an adjustment value corresponding to the transmission power of the branch A with reference to the attenuation table 160 in the storage unit 16. The control unit 15 then sets the acquired attenuation to the attenuator 36 in the branch A. Thus, the attenuation set to the attenuator 36 in the branch A is changed, for example, as depicted in FIG. 5B.

Then, when the update timing for the LUT 23 in the branch A comes, the control unit 15 sets the acquired gain adjustment value to the gain adjusting unit 25 in the branch A. Thus, the operation status of the gain adjusting unit 25 in the branch A is changed, for example, as depicted in FIG. 5C. In FIG. 5C, a high state indicates a state in which the gain adjusting unit 25 in the branch A is amplifying the feedback signal by following the gain adjustment value set by the control unit 15. Also in FIG. 5C, a low state indicates a state in which the gain adjusting unit 25 in the branch A stops amplifying the feedback signal.

Then, while the gain adjusting unit 25 is amplifying the feedback signal, the updating unit 24 in the branch A updates the distortion compensation coefficient in the LUT 23 at a timing, for example, depicted in FIG. 5D, based on the transmission signal and the feedback signal amplified by the gain adjusting unit 25. In FIG. 5D, a high state indicates a state in which the updating unit 24 in the branch A is updating the distortion compensation coefficient in the LUT 23. Also in FIG. 5D, a low state indicates a state in which the updating unit 24 in the branch A stops updating the distortion compensation coefficient in the LUT 23, that is, a state in which the distortion compensation coefficient in the LUT 23 is retained.

Similarly, as for the branch B, when the transmission power of the branch B is changed, for example, as depicted in FIG. 5E, the control unit 15 acquires an attenuation and an adjustment value corresponding to the transmission power of the branch B with reference to the attenuation table 160 in the storage unit 16. The control unit 15 then sets the acquired attenuation to the attenuator 36 in the branch B. Thus, the attenuation set to the attenuator 36 in the branch B is changed, for example, as depicted in FIG. 5F.

Then, when the update timing for the LUT 23 in the branch B comes, the control unit 15 sets the acquired gain adjustment value to the gain adjusting unit 25 in the branch B. Thus, the operation status of the gain adjusting unit 25 in the branch B is changed, for example, as depicted in FIG. 5G. In FIG. 5G, a high state indicates a state in which the gain adjusting unit 25 in the branch B is amplifying the feedback signal by following the gain adjustment value set by the control unit 15. Also in FIG. 5G, a low state indicates a state in which the gain adjusting unit 25 in the branch B stops amplifying the feedback signal.

Then, while the gain adjusting unit 25 is amplifying the feedback signal, the updating unit 24 in the branch B updates the distortion compensation coefficient in the LUT 23 at a timing, for example, depicted in FIG. 5H, based on the transmission signal and the feedback signal amplified by the gain adjusting unit 25. In FIG. 5H, a high state indicates a state in which the updating unit 24 in the branch B is updating the distortion compensation coefficient in the LUT 23. Also in FIG. 5H, a low state indicates a state in which the updating unit 24 in the branch B stops updating the distortion compensation coefficient in the LUT 23, that is, a state in which the distortion compensation coefficient in the LUT 23 is retained.

In the present embodiment, for example, as depicted in FIG. 5C and FIG. 5G, when the update timing for the LUT 23 comes, the gain adjusting unit 25 starts amplifying the feedback signal before the updating unit 24 starts updating the LUT 23. The gain adjusting unit 25 then stops amplifying the feedback signal when the update of the LUT 23 by the updating unit 24 ends. However, the disclosed technology is not limited to this. For example, while a transmission signal is being transmitted in each branch, the gain adjusting unit 25 may continue amplification of the feedback signal in accordance with an adjustment value indicated by the control unit 15. However, in view of reduction in power consumption of the distortion compensating unit 20, amplification of the feedback signal by the gain adjusting unit 25 only when the updating unit 24 updates the LUT 23 is preferable.

Also while the update timing for the LUT 23 in the branch A and the update timing for the LUT 23 in the branch B are different from each other in the example depicted in FIG. 5A to FIG. 5H, these timings may not be different from each other.

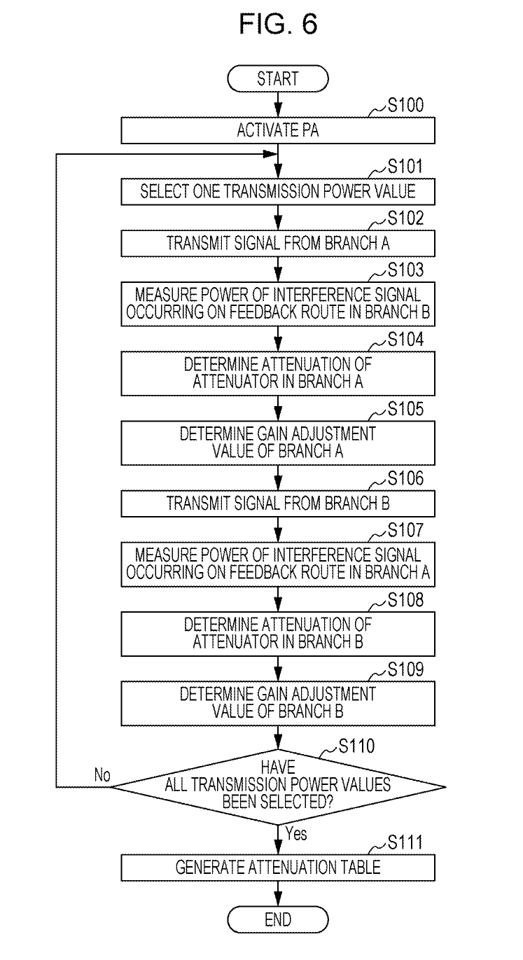

FIG. 6 is a flowchart of an example of attenuation table generation process. The flowchart depicted in FIG. 6 is performed at a predetermined timing, for example, at the time of factory shipping of the distortion compensating unit 20.

The control unit 15 first powers up the PA 34 in each branch to activate each PA 34 (S100). The gain adjusting unit 25 then selects one transmission power value from among a plurality of transmission power values set in advance (S101). The control unit 15 then causes a signal to be transmitted in the branch A (S102). Here, no signal is transmitted in the branch B.

Next, the control unit 15 measures a power (for example, the power Pᵢₐ depicted in FIG. 3B) of the interference signal occurring on the feedback route in the branch B (S103). The control unit 15 then determines an attenuation corresponding to a power difference (for example, ΔPᵢₐ depicted in FIG. 3B) between the measured power of the interference signal and the noise floor as an attenuation to be set to the attenuator 36 in the branch A (S104).

Next, the control unit 15 determines a gain for recovering the power attenuated by the determined attenuation as a gain adjustment value of the branch A (S105). The control unit 15 then retains the attenuation and the adjustment value determined for the branch A in association with the transmission power value selected at step S101.

Next, the control unit 15 stops signal transmission from the branch A, and causes a signal to be transmitted in the branch B (S106). The control unit 15 then measures a power (for example, the power P_{ib} depicted in FIG. 3A) of the interference signal occurring on the feedback route in the branch A (S107). The control unit 15 then determines an attenuation corresponding to a power difference (for example, ΔP_{ib} depicted in FIG. 3A) between the measured power of the interference signal and the noise floor as an attenuation to be set to the attenuator 36 in the branch B (S108).

Next, the control unit 15 determines a gain for recovering the power attenuated by the determined attenuation as a gain adjustment value of the branch B (S109). The control unit 15 then retains the attenuation and the adjustment value determined for the branch B in association with the transmission power value selected at step S101.

Next, the control unit 15 determines whether all of the plurality of transmission power values have been selected (S110). When an unselected value is present among the plurality of transmission power values (No at S110), the control unit 15 performs the process at step S101 again. On the other hand, if all of the plurality of transmission power values have been selected (Yes at S110), the control unit 15 generates the attenuation table 160, for example, described with reference to FIG. 2, by using the attenuation and the adjustment value determined for each transmission power for each branch (S111). The control unit 15 then stores the generated attenuation table 160 in the storage unit 16, and ends the attenuation table generation process depicted in the flowchart.

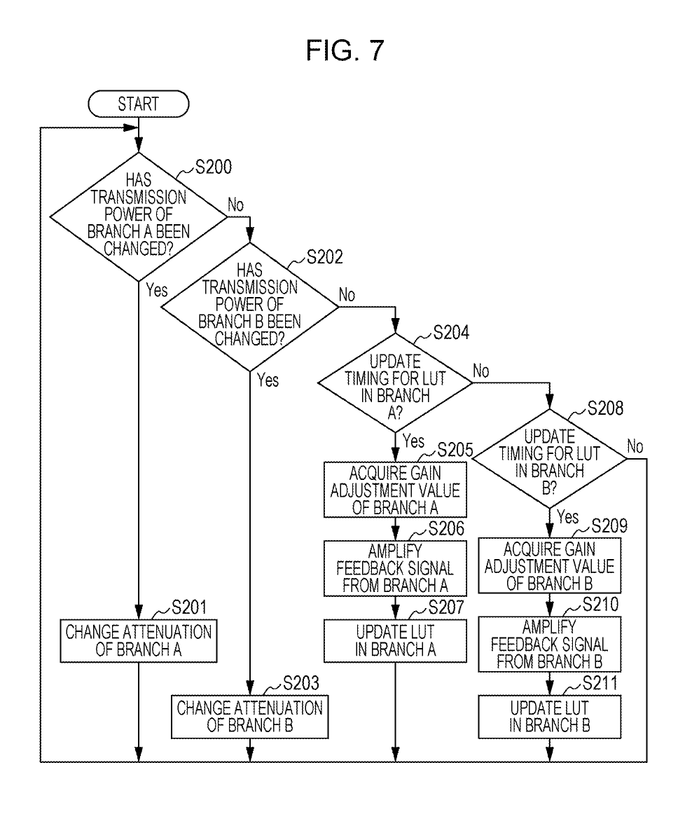

FIG. 7 is a flowchart of an example of update process in the first embodiment. For example, when transmission of a transmission signal starts in the branch A and the branch B, the base station 10 starts update process, for example, depicted in the flowchart of FIG. 7.

The control unit 15 first determines whether the transmission power of the branch A has been changed (S200). If the transmission power of the branch A has been changed (Yes at S200), the control unit 15 acquires an attenuation corresponding to the current transmission power of the branch A with reference to the attenuation table 160 in the storage unit 16. The control unit 15 then sets the acquired attenuation to the attenuator 36 in the branch A, thereby changing the attenuation of the attenuator 36 in the branch A (S201). The control unit 15 then performs the process at step S200 again.

If the transmission power of the branch A has not been changed (No at S200), the control unit 15 determines whether the transmission power of the branch B has been changed (S202). If the transmission power of the branch B has been changed (Yes at S202), the control unit 15 acquires an attenuation corresponding to the current transmission power of the branch B with reference to the attenuation table 160 in the storage unit 16. The control unit 15 then sets the acquired attenuation to the attenuator 36 in the branch B, thereby changing the attenuation of the attenuator 36 in the branch B (S203). The control unit 15 then performs the process at step S200 again.

If the transmission power of the branch B has not been changed (No at S202), the control unit 15 determines whether the update timing for the LUT 23 in the branch A comes (S204). When the update timing for the LUT 23 in the branch A comes (Yes at S204), the control unit 15 acquires a gain adjustment value corresponding to the current transmission power of the branch A with reference to the attenuation table 160 in the storage unit 16 (S205). The control unit 15 then sets the acquired gain adjustment value to the gain adjusting unit 25 in the branch A.

The gain adjusting unit 25 in the branch A amplifies the feedback signal outputted from the analog transmitting unit 30 in the branch A via the ADC 12 in accordance with the set gain adjustment value (S206). The updating unit 24 in the branch A then updates the distortion compensation coefficient in the LUT 23 based on the transmission signal and the feedback signal amplified by the gain adjusting unit 25 (S207). The control unit 15 then performs the process at step S200 again.

When the updating timing for the LUT 23 in the branch A does not come (No at S204), the control unit 15 determines whether the update timing for the LUT 23 in the branch B comes (S208). When the update timing for the LUT 23 in the branch B does not come (No at S208), the control unit 15 performs the process at step S200 again.

When the update timing for the LUT 23 in the branch B comes (Yes at S208), the control unit 15 acquires a gain adjustment value corresponding to the current transmission power of the branch B with reference to the attenuation table 160 in the storage unit 16 (S209). The control unit 15 then sets the acquired gain adjustment value to the gain adjusting unit 25 in the branch B.

The gain adjusting unit 25 in the branch B amplifies the feedback signal outputted from the analog transmitting unit 30 in the branch B via the ADC 12 in accordance with the set gain adjustment value (S210). The updating unit 24 in the branch B then updates the distortion compensation coefficient in the LUT 23 based on the transmission signal and the feedback signal amplified by the gain adjusting unit 25 (S211). The control unit 15 then performs the process at step S200 again.

As evident from the above description, the base station 10 of the present embodiment has the plurality of transmitters 50 which each transmit a distortion-compensated transmission signal. The transmitter 50 has the PA 34, the feedback route, and the distortion compensating unit 20. The PA 34 amplifies and outputs the transmission signal. The feedback route attenuates an output from the PA 34 and feeds back a signal of the attenuated output. The distortion compensating unit 20 performs distortion compensation based on a distortion compensation coefficient calculated based on the signal fed back via the feedback route. As described above, in the base station 10 of the present embodiment, the signal flowing through the feedback route in each transmitter 50 is attenuated by the attenuator 36. This reduces the power of the signal flowing through the feedback route in each transmitter 50 and also reduces the power of the interference signal occurring on the feedback route in another transmitter 50. This reduces the power of the interference signal included in the signal fed back to the distortion compensating unit 20 in each transmitter 50. The distortion compensating unit 20 in each transmitter 50 then performs distortion compensation based on the signal with the reduced interference signal. This allows the base station 10 to accurately compensate for distortion of the PA 34 in each transmitter 50.

Also, the base station 10 of the present embodiment further has the updating unit 24 which updates the distortion compensation coefficient based on the signal fed back via the feedback route. This allows the distortion compensation coefficient in the LUT 23 to be accurately updated. Therefore, the base station 10 is allowed to accurately compensate for distortion of the PA 34 in each transmitter 50.

The base station 10 of the present embodiment also has the gain adjusting unit 25 which amplifies the power of the signal fed back via the feedback route in accordance with the attenuation by the feedback route. The distortion compensating unit 20 performs distortion compensation by using the distortion compensation coefficient based on the signal amplified by the gain adjusting unit 25. This makes the power of the feedback signal outputted from the coupler 35 and the power of the feedback signal inputted to the updating unit 24 in the distortion compensating unit 20 approximately equal to each other in each transmitter 50. This decreases a deviation of the power of the feedback signal inputted to the updating unit 24 and allows the distortion compensating unit 20 to accurately compensate for distortion of the PA 34 in each transmitter 50.

Also, in the base station 10 of the present embodiment, the feedback route includes the attenuator 36 which attenuates the power of the signal, and the attenuator 36 attenuates the power of the signal flowing through the feedback route so that the power of the interference signal occurring, due to the signal, on another feedback route is equal to or smaller than a predetermined power. The predetermined power is, for example, the power of the noise floor present in the feedback route. This allows the base station 10 to inhibit degradation in accuracy of distortion compensation.

Furthermore, in the base station 10 of the present embodiment, the feedback route includes the attenuator 36 which attenuates the power of the signal, and the attenuator 36 changes the attenuation of the power of the signal flowing through the feedback route in accordance with the power of the transmission signal inputted to the PA 34. Thus, each attenuator 36 is allowed to reliably decrease the power of the interference signal occurring, due to the signal flowing through the feedback route where the attenuator 36 is provided, on another feedback route to a power equal to or smaller than a predetermined power. This allows the base station 10 to inhibit degradation in accuracy of distortion compensation.

### Second Embodiment

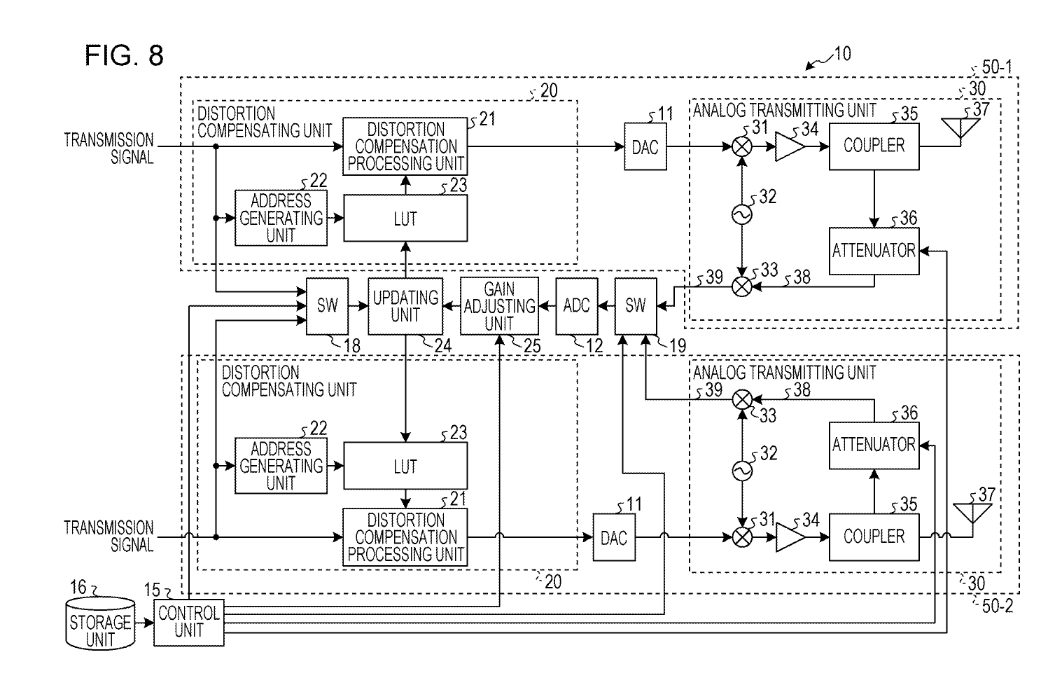

FIG. 8 is a block diagram of an example of the base station 10 in a second embodiment. The base station 10 in the present embodiment has the ADC 12, the control unit 15, the storage unit 16, the SW 18, the SW 19, the updating unit 24, the gain adjusting unit 25, and the plurality of transmitters 50-1 and 50-2. In FIG. 8, except for points described further below, a block provided with the same reference numeral as that in FIG. 1 has a function identical or similar to that of the relevant block depicted in FIG. 1, and therefore is not described herein. The base station 10 in the present embodiment is different from the base station 10 in the first embodiment in that one set of the ADC 12, the updating unit 24, and the gain adjusting unit 25 is provided in common for the plurality of transmitters 50.

In each transmitter 50, the feedback signal subjected to a process such as down-conversion by the down-converter 33 is inputted to the SW 19 via the wiring 39. The SW 19 selects either one of the feedback signal outputted from the transmitter 50-1 and the feedback signal outputted from the transmitter 50-2 in accordance with a control signal from the control unit 15. The SW 19 then outputs the selected feedback signal to the ADC 12. The SW 19 is an example of a selection circuit. The ADC 12 converts the feedback signal outputted from the SW 19 from an analog signal to a digital signal, and outputs the converted feedback signal to the gain adjusting unit 25. The gain adjusting unit 25 amplifies the power of the feedback signal outputted from the ADC 12 in accordance with the gain adjustment value indicated by the control unit 15.

The SW 18 selects either one of the transmission signal inputted to the transmitter 50-1 and the transmission signal inputted to the transmitter 50-2 in accordance with a control signal from the control unit 15. The SW 18 then outputs the selected transmission signal to the updating unit 24. The updating unit 24 calculates a distortion compensation coefficient based on the transmission signal outputted from the SW 18 and the feedback signal amplified by the gain adjusting unit 25. The updating unit 24 then updates the distortion compensation coefficient in the LUT 23 with the calculated distortion compensation coefficient.

As described above, the base station 10 in the present embodiment is provided with one set of the ADC 12, the updating unit 24, and the gain adjusting unit 25 in common for the plurality of transmitters 50. This allows reduction in circuit size of the base station 10.

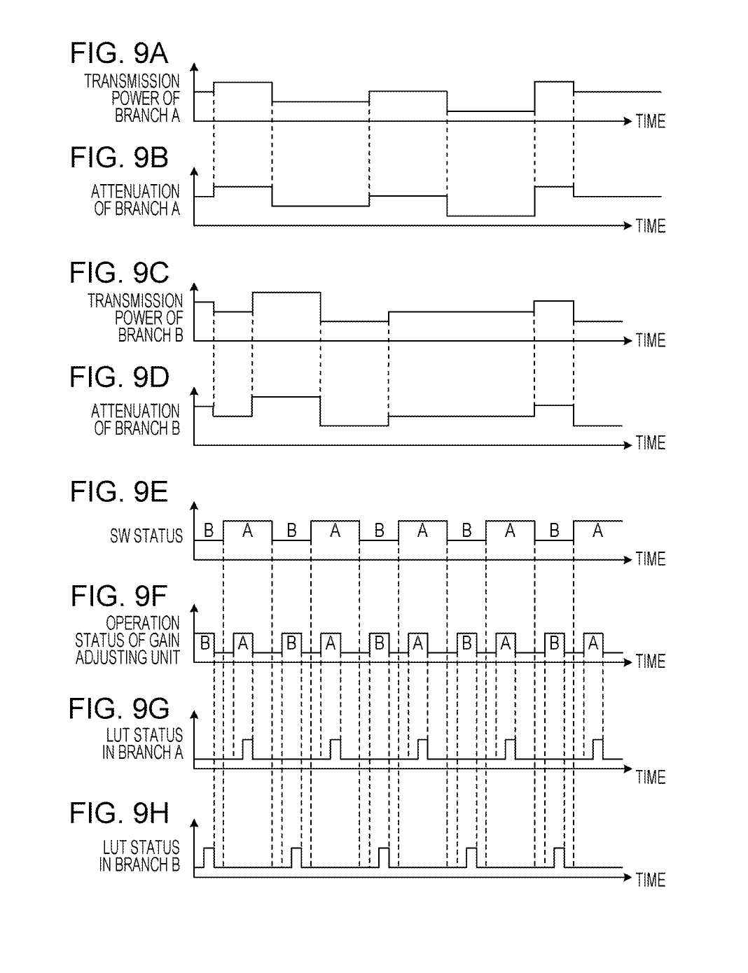

FIG. 9A to FIG. 9H are timing diagrams of an example of timing of update process in the second embodiment. When the transmission power of the branch A is changed, for example, as depicted in FIG. 9A, the control unit 15 acquires an attenuation and an adjustment value corresponding to the transmission power of the branch A with reference to the attenuation table 160 in the storage unit 16. The control unit 15 then sets the acquired attenuation to the attenuator 36 in the branch A. Thus, the attenuation set to the attenuator 36 in the branch A is changed, for example, as depicted in FIG. 9B.

Meanwhile, when the transmission power of the branch B is changed, for example, as depicted in FIG. 9C, the control unit 15 acquires an attenuation and an adjustment value corresponding to the transmission power of the branch B with reference to the attenuation table 160 in the storage unit 16. The control unit 15 then sets the acquired attenuation to the attenuator 36 in the branch B. Thus, the attenuation set to the attenuator 36 in the branch B is changed, for example, as depicted in FIG. 9D.

For example, as depicted in FIG. 9E, the control unit 15 controls the SW 18 and the SW 19 so that the branch A is selected at the updating timing for the LUT 23 in the branch A and the branch B is selected at the updating timing for the LUT 23 in the branch B. In FIG. 9E, a high state indicates a state in which the branch A is selected by the SW 18 and the SW 19, and a low state indicates a state in which the branch B is selected by the SW 18 and the SW 19.

Also, when the update timing for the LUT 23 in the branch A comes, the control unit 15 sets the acquired gain adjustment value to the gain adjusting unit 25 in the branch A. Meanwhile, when the update timing for the LUT 23 in the branch B comes, the control unit 15 sets the acquired gain adjustment value to the gain adjusting unit 25 in the branch B. Thus, the operation status of the gain adjusting unit 25 is changed, for example, as depicted in FIG. 9F. In FIG. 9F, a high state indicates a state in which the gain adjusting unit 25 in the branch A or the branch B is amplifying the feedback signal by following the gain adjustment value set by the control unit 15. Also in FIG. 9F, a low state indicates a state in which the gain adjusting unit 25 in any branch stops amplifying the feedback signal. For example, as depicted in FIG. 9F, the gain adjusting unit 25 amplifies the feedback signal of the branch A while the SW 18 and the SW 19 select the branch A, and amplifies the feedback signal of the branch B while the SW 18 and the SW 19 select the branch B.

The updating unit 24 then updates the distortion compensation coefficient in the LUT 23 in the branch A based on the transmission signal selected by the SW 18 and the feedback signal amplified by the gain adjusting unit 25 while the SW 18 and the SW 19 select the branch A. This causes the distortion compensation coefficient in the LUT 23 in the branch A to be updated at a timing, for example, depicted in FIG. 9G. The updating unit 24 also updates the distortion compensation coefficient in the LUT 23 in the branch B based on the transmission signal selected by the SW 18 and the feedback signal amplified by the gain adjusting unit 25 while the SW 18 and the SW 19 select the branch A. This causes the distortion compensation coefficient in the LUT 23 in the branch B to be updated at a timing, for example, depicted in FIG. 9H. In FIG. 9G and FIG. 9H, a high state indicates a state in which the updating unit 24 is updating the distortion compensation coefficient in the LUT 23. Also in FIG. 9G and FIG. 9H, a low state indicates a state in which the updating unit 24 stops updating the distortion compensation coefficient in the LUT 23, that is, a state in which the distortion compensation coefficient in the LUT 23 is retained.

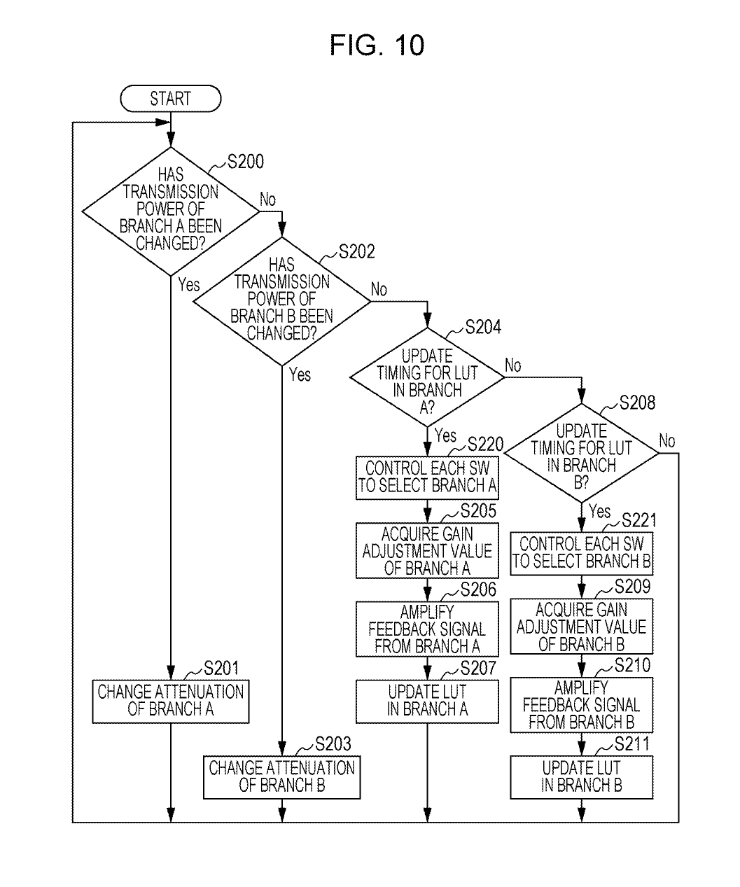

FIG. 10 is a flowchart of an example of update process in the second embodiment. In FIG. 10, except for points described further below, a process provided with the same reference character as that in FIG. 7 is similar to the relevant process described in FIG. 7, and therefore is not described herein.

When the update timing for the LUT 23 in the branch A comes (Yes at S204), the control unit 15 controls the SW 18 and the SW 19 so that the branch A is selected (S220). The control unit 15 then performs the process at step S205.

Meanwhile, when the update timing for the LUT 23 in the branch B comes (Yes at S208), the control unit 15 controls the SW 18 and the SW 19 so that the branch B is selected (S221). The control unit 15 then performs the process at step S209.

As evident from the above description, the base station 10 of the present embodiment has the SW 19 and the gain adjusting unit 25. The SW 19 selects any of the feedback routes included in each transmitter 50. The gain adjusting unit 25 amplifies the power of the signal fed back via the feedback route selected by the SW 19 in accordance with the attenuation by the feedback route. Also, the updating unit 24 calculates a distortion compensation coefficient of the relevant transmitter 50 based on the signal amplified by the gain adjusting unit 25. This allows the base station 10 to accurately compensate for distortion of the PA 34 in each transmitter 50. Also, the circuit size of the base station 10 is reduced.

In the second embodiment, for example, as depicted in FIG. 9F, when the update timing for the LUT 23 in each branch comes, the gain adjusting unit 25 starts amplifying the feedback signal before the updating unit 24 starts updating the LUT 23. The gain adjusting unit 25 then stops amplifying the feedback signal when the update of the LUT 23 by the updating unit 24 ends. However, the disclosed technology is not limited to this. The gain adjusting unit 25 may start amplifying the feedback signal of the branch selected by the SW 18 and the SW 19 at the timing of switching the branch selected by the SW 18 and the SW 19. However, in view of reduction in power consumption of the base station 10, amplification of the feedback signal by the gain adjusting unit 25 only when the updating unit 24 updates the LUT 23 is preferable.

### Third Embodiment

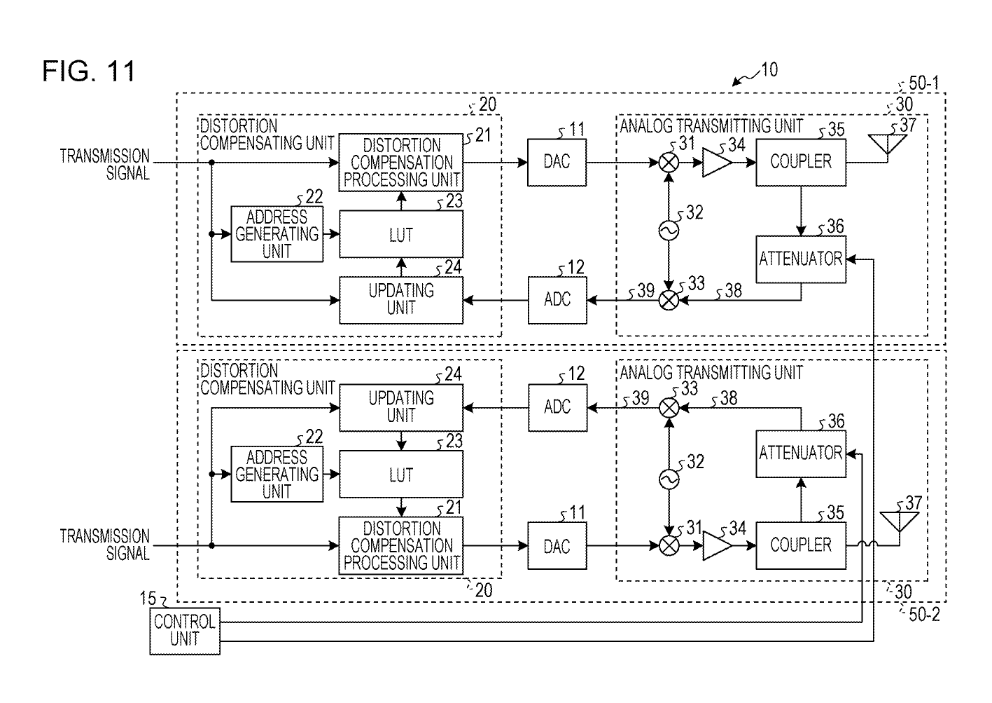

FIG. 11 is a block diagram of an example of the base station 10 in a third embodiment. The base station 10 in the present embodiment has the control unit 15 and the plurality of transmitters 50-1 and 50-2. The control unit 15 in the present embodiment is an example of a setting unit. In FIG. 11, except for points described further below, a block provided with the same reference numeral as that in FIG. 1 has a function identical or similar to that of the relevant block depicted in FIG. 1, and therefore is not described herein. The base station 10 in the present embodiment is different from the base station 10 in the first embodiment in that, when the LUT 23 in one branch is updated, the first attenuation is set to the attenuator 36 in that branch and the second attenuation is set to the attenuator 36 in another branch. The second attenuation is larger than the first attenuation.

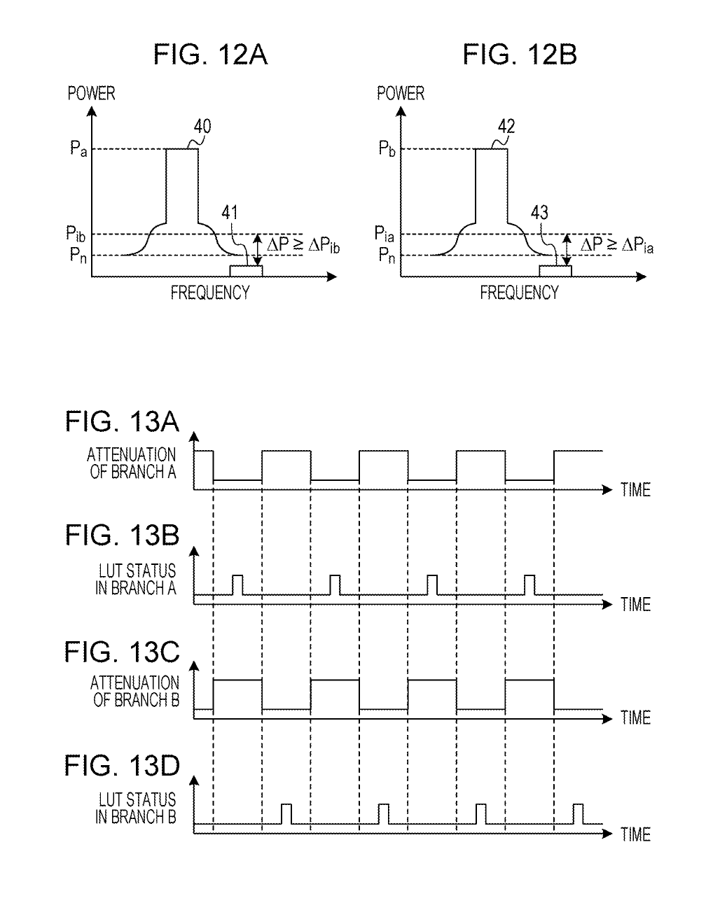

Specifically, the control unit 15 sets the first attenuation to the attenuator 36 in the branch A at the update timing for the LUT 23 in the branch A. The first attenuation is, for example, 0. The control unit 15 also sets the second attenuation to the attenuator 36 in a branch other than the branch A (in the present embodiment, the branch B) at the update timing for the LUT 23 in the branch A. Thus, the frequency spectrum of the signal flowing through the feedback route in the branch A (for example, the wiring 38 in the branch A) is, for example, as depicted in FIG. 12A.

In the present embodiment, the second attenuation set to the attenuator 36 in the branch B is, for example, as depicted in FIG. 12A, an attenuation ΔP at any power of the transmission signal transmitted in the branch B, the attenuation ΔP which decreases the power of the interference signal 41 occurring on the feedback route in the branch A to a power equal to or smaller than the power Pₙ of the noise floor.

Also, the control unit 15 sets the first attenuation to the attenuator 36 in the branch B at the update timing for the LUT 23 in the branch B. The control unit 15 also sets the second attenuation to the attenuator 36 in a branch other than the branch B (in the present embodiment, the branch A) at the update timing for the LUT 23 in the branch B. Thus, the frequency spectrum of the signal flowing through the feedback route in the branch B is, for example, as depicted in FIG. 12B.

In the present embodiment, the second attenuation set to the attenuator 36 in the branch A is, for example, as depicted in FIG. 12B, the attenuation ΔP at any power of the transmission signal transmitted in the branch A, the attenuation ΔP which decreases the power of the interference signal 43 occurring on the feedback route in the branch B to a power equal to or smaller than the power Pₙ of the noise floor.

The second attenuation may be, for example, equal to or larger than several tens of dB. The attenuator 36 in each branch may be a switch which switches between conduction or interruption of the output from the coupler 35 and the wiring 38. Also, the use of this switch allows the attenuation of the feedback signal flowing through the feedback route in each branch to be switched between the first attenuation and the second attenuation.

As described above, in the base station 10 in the present embodiment, when the LUT 23 in one branch is updated, the first attenuation is set to the attenuator 36 in that branch and the second attenuation larger than the first attenuation is set to the attenuator 36 in another branch. With this, in the feedback route in the branch having the LUT 23 as an update target, the power of the interference signal from the feedback route in another branch is reduced. This allows the base station 10 to accurately calculate the distortion compensation coefficient for compensating for distortion of the PA 34 in each transmitter 50. This allows the base station 10 to accurately compensate for distortion of the PA 34 in each transmitter 50.

FIG. 13A to FIG. 13D are timing diagrams of an example of timing of update process in the third embodiment. For example, as depicted in FIG. 13A, the control unit 15 sets the first attenuation to the attenuator 36 in the branch A at the update timing for the LUT 23 in the branch A. Also, the control unit 15 sets the second attenuation to the attenuator 36 in the branch A in a period other than the update timing for the LUT 23 in the branch A. In FIG. 13A, a high state indicates a state in which the second attenuation is set, and a low state indicates a state in which the first attenuation is set.

Then, for example, as depicted in FIG. 13B, the updating unit 24 in the branch A updates the distortion compensation coefficient in the LUT 23 in the branch A at the update timing for the LUT 23 in the branch A, based on the transmission signal inputted to the branch A and the feedback signal of the branch A. In FIG. 13B, a high state indicates a state in which the updating unit 24 is updating the distortion compensation coefficient in the LUT 23. Also in FIG. 13B, a low state indicates a state in which the updating unit 24 stops updating the distortion compensation coefficient in the LUT 23, that is, a state in which the distortion compensation coefficient in the LUT 23 is retained.

Also, for example, as depicted in FIG. 13C, the control unit 15 sets the first attenuation to the attenuator 36 in the branch B at the update timing for the LUT 23 in the branch B. Also, the control unit 15 sets the second attenuation to the attenuator 36 in the branch B in a period other than the update timing for the LUT 23 in the branch B. In FIG. 13C, a high state indicates a state in which the second attenuation is set, and a low state indicates a state in which the first attenuation is set.

Then, for example, as depicted in FIG. 13D, the updating unit 24 in the branch B updates the distortion compensation coefficient in the LUT 23 in the branch B at the updating timing for the LUT 23 in the branch B, based on the transmission signal inputted to the branch B and the feedback signal of the branch B. In FIG. 13D, a high state indicates a state in which the updating unit 24 is updating the distortion compensation coefficient in the LUT 23. Also in FIG. 13D, a low state indicates a state in which the updating unit 24 stops updating the distortion compensation coefficient in the LUT 23, that is, a state in which the distortion compensation coefficient in the LUT 23 is retained.

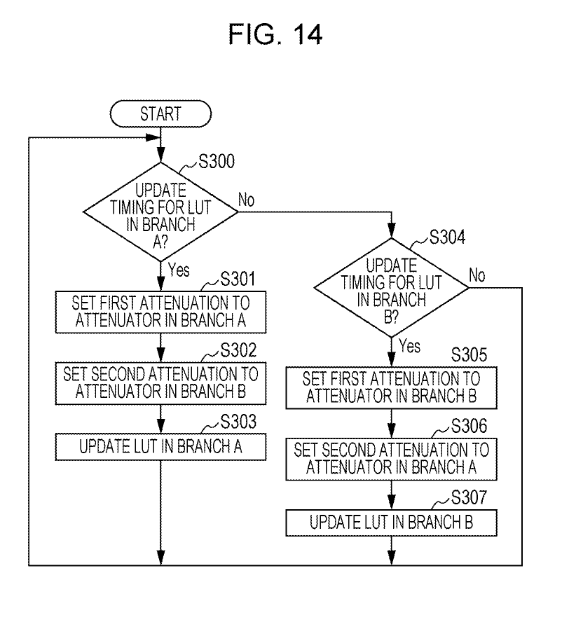

FIG. 14 is a flowchart of an example of update process in the third embodiment. For example, when transmission of the transmission signal starts in the branch A and the branch B, the base station 10 starts update process, for example, depicted in the flowchart of FIG. 14.

The control unit 15 first determines whether the update timing for the LUT 23 in the branch A comes (S300). When the update timing for the LUT 23 in the branch A comes (Yes at S300), the control unit 15 sets the first attenuation to the attenuator 36 in the branch A (S301). The control unit 15 then sets the second attenuation to the attenuator 36 in the branch B (S302). The updating unit 24 then updates the distortion compensation coefficient in the LUT 23 based on the transmission signal inputted to the branch A and the feedback signal of the branch A (S303). The control unit 15 then performs the process at step S300.

When the update timing for the LUT 23 in the branch A does not come (No at S300), the control unit 15 determines whether the update timing for the LUT 23 in the branch B comes (S304). When the update timing for the LUT 23 in the branch B does not come (No at S304), the control unit 15 performs the process at step S300.

When the update timing for the LUT 23 in the branch B comes (Yes at S304), the control unit 15 sets the first attenuation to the attenuator 36 in the branch B (S305). The control unit 15 then sets the second attenuation to the attenuator 36 in the branch A (S306). The updating unit 24 then updates the distortion compensation coefficient in the LUT 23 based on the transmission signal inputted to the branch B and the feedback signal of the branch B (S307). The control unit 15 then performs the process at step S300.

As evident from the above description, the base station 10 of the present embodiment further has the control unit 15 which sequentially selects, one by one, the attenuators 36 which are included in the feedback routes included in the plurality of transmitters 50 and attenuate the power of the signal, and sets the first attenuation to the selected attenuator 36 and sets the second attenuation to the attenuator 36 other than the selected attenuator 36. The updating unit 24 calculates the distortion compensation coefficient based on the signal fed back via the feedback route where the attenuator 36 with the first attenuation set by the control unit 15 is provided. This allows the base station 10 to accurately calculate the distortion compensation coefficient for compensating for distortion of the PA 34 in the transmitter 50. This allows the base station 10 to accurately compensate for distortion of the PA 34 in each transmitter 50.

### Fourth Embodiment

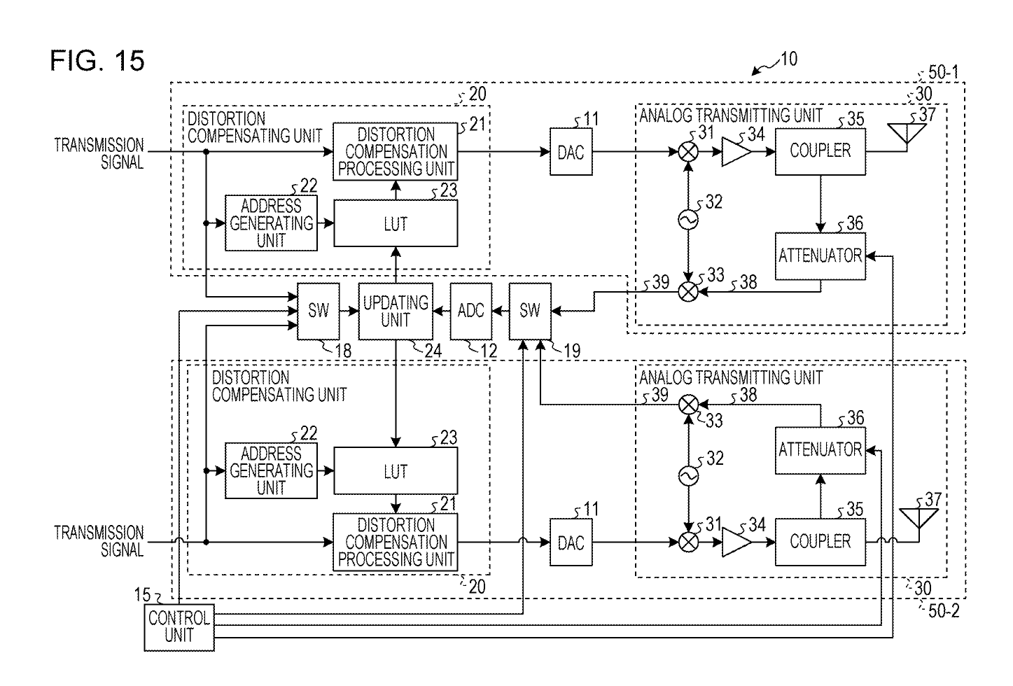

FIG. 15 is a block diagram of an example of the base station 10 in a fourth embodiment. The base station 10 in the present embodiment has the ADC 12, the control unit 15, the SW 18, the SW 19, the updating unit 24, and the plurality of transmitters 50-1 and 50-2. In FIG. 15, except for points described further below, a block provided with the same reference numeral as that in FIG. 11 has a function identical or similar to that of the relevant block depicted in FIG. 11, and therefore is not described herein. The base station 10 in the present embodiment is different from the base station 10 in the third embodiment in that one set of the ADC 12 and the updating unit 24 is provided in common for the plurality of transmitters 50.

In each transmitter 50, the feedback signal subjected to a process such as down-conversion by the down-converter 33 is inputted to the SW 19 via the wiring 39. The SW 19 selects either one of the feedback signal outputted from the transmitter 50-1 and the feedback signal outputted from the transmitter 50-2 in accordance with a control signal from the control unit 15. The SW 19 then outputs the selected feedback signal to the ADC 12. The SW 19 is an example of a selection circuit. The ADC 12 converts the feedback signal outputted from the SW 19 from an analog signal to a digital signal, and outputs the converted feedback signal to the updating unit 24.

The SW 18 selects either one of the transmission signal inputted to the transmitter 50-1 and the transmission signal inputted to the transmitter 50-2 in accordance with a control signal from the control unit 15. The SW 18 then outputs the selected transmission signal to the updating unit 24. The updating unit 24 calculates a distortion compensation coefficient based on the transmission signal outputted from the SW 18 and the feedback signal outputted from the ADC 12. The updating unit 24 then updates the distortion compensation coefficient in the LUT 23 with the calculated distortion compensation coefficient.

As described above, the base station 10 in the present embodiment is provided with one set of the ADC 12 and the updating unit 24 in common for the plurality of transmitters 50. This allows reduction in circuit size of the base station 10.

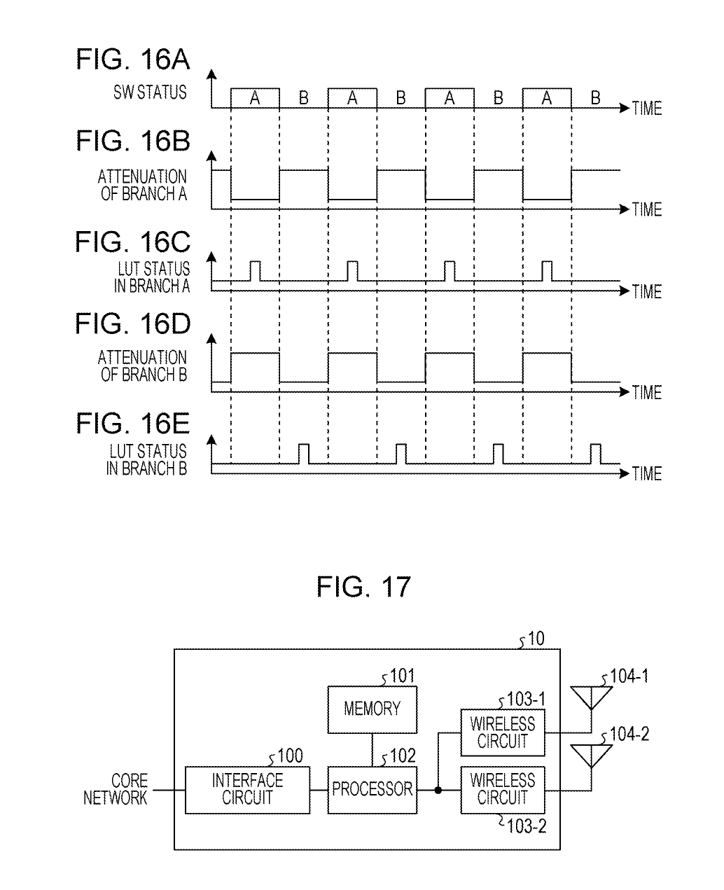

FIG. 16A to FIG. 16E are timing diagrams of an example of timing of update process in the fourth embodiment. For example, as depicted in FIG. 16A, the control unit 15 controls the SW 18 and the SW 19 so that the branch A is selected at the update timing for the LUT 23 in the branch A and the branch B is selected at the update timing for the LUT 23 in the branch B. In FIG. 16A, a high state indicates a state in which the branch A is selected by the SW 18 and the SW 19, and a low state indicates a state in which the branch B is selected by the SW 18 and the SW 19.

Also, the control unit 15 sets the first attenuation to the attenuator 36 in the branch A and sets the second attenuation larger than the first attenuation to the attenuator 36 in the branch B at the update timing for the LUT 23 in the branch A. The control unit 15 also sets the first attenuation to the attenuator 36 in the branch B and sets the second attenuation to the attenuator 36 in the branch A at the update timing for the LUT 23 in the branch B. Thus, the attenuation set to the attenuator 36 in the branch A is changed, for example, as depicted in FIG. 16B, and the attenuation set to the attenuator 36 in the branch B is changed, for example, as depicted in FIG. 16D.

While the SW 18 and the SW 19 select the branch A, the updating unit 24 updates the distortion compensation coefficient in the LUT 23 in the branch A based on the transmission signal selected by the SW 18 and the feedback signal outputted from the ADC 12. Thus, the distortion compensation coefficient in the LUT 23 in the branch A is updated at a timing, for example, depicted in FIG. 16C. Also, while the SW 18 and the SW 19 select the branch B, the updating unit 24 updates the distortion compensation coefficient in the LUT 23 in the branch B based on the transmission signal selected by the SW 18 and the feedback signal outputted from the ADC 12. Thus, the distortion compensation coefficient in the LUT 23 in the branch B is updated at a timing, for example, depicted in FIG. 16E. In FIG. 16C and FIG. 16E, a high state indicates a state in which the updating unit 24 is updating the distortion compensation coefficient in the LUT 23. Also in FIG. 16C and FIG. 16E, a low state indicates a state in which the updating unit 24 stops updating the distortion compensation coefficient in the LUT 23, that is, a state in which the distortion compensation coefficient in the LUT 23 is retained.

As evident from the above description, the base station 10 of the present embodiment has the SW 19 which selects a feedback route provided with the attenuator 36 with the first attenuation set by the control unit 15 from among the feedback routes included respectively in the plurality of transmitters 50. The updating unit 24 is singly provided in common for the plurality of transmitters 50, and calculates the distortion compensation coefficient based on the signal fed back via the feedback route selected by the SW 19. This allows the base station 10 to accurately compensate for distortion of the PA 34 in each transmitter 50. Also, the circuit size of the base station 10 is reduced.

The base station 10 in each of the above-described embodiments is implemented by hardware, for example, as the one depicted in FIG. 17. FIG. 17 is a diagram of an example of hardware of the base station 10. For example, as depicted in FIG. 17, the base station 10 has an interface circuit 100, a memory 101, a processor 102, a plurality of wireless circuit 103-1 and 103-2, and a plurality of antennas 104-1 and 104-2. In the following, the plurality of wireless circuits 103-1 and 103-2 are collectively and simply referred to as a wireless circuit 103 when not distinguished from each other, and the plurality of antennas 104-1 and 104-2 are collectively and simply referred to as an antenna 104 when not distinguished from each other.

The interface circuit 100 is an interface for connection to a core network via wired connection. Each wireless circuit 103 performs a process such as up-conversion on a signal outputted from the processor 102, and transmits the processed signal via any antenna 104. Also, each wireless circuit 103 has the PA 34, and performs a process such as down-conversion on part of signal outputted from the PA 34 for feedback to the processor 102. Each wireless circuit 103 implements the functions of the DAC 11, the ADC 12, and the analog transmitting unit 30 in the transmitter 50.

In the memory 101, for example, various programs and so forth are stored, such as those for implementing the functions of the control unit 15, the storage unit 16, the SW 18, the SW 19, the distortion compensating unit 20, and so forth. By executing a program read from the memory 101, the processor 102 implements, for example, the function of each of the control unit 15, the storage unit 16, the SW 18, the SW 19, the distortion compensating unit 20, and so forth. While one processor 102 is provided in the base station 10 illustrated in FIG. 17, a plurality of such processors 102 may be provided.

The disclosed technology is not limited to each of the above-described embodiments, and may be variously modified in a range of the gist of the disclosed technology.

For example, in each of the above-described embodiments, the attenuator 36 in each branch attenuates the power of the feedback signal outputted from the coupler 35. The feedback signal with the power attenuated by the attenuator 36 is then fed back to the distortion compensating unit 20 via the wiring 38, the down-converter 33, and the wiring 39. However, the disclosed technology is not limited to this. For example, in each branch, the attenuator 36 may be disposed not on the wiring 38 between the coupler 35 and the down-converter 33 but on the wiring 39 between the down-converter 33 and the ADC 12.

In this case, an interference signal from another branch occurs on the feedback route in each branch. This interference signal is attenuated by the attenuator 36 disposed on the wiring 39. This decreases, by the attenuator 36 disposed on the wiring 39, the feedback signal in the signal to be fed back to the distortion compensating unit 20, but also decreases the power of the interference signal. This allows degradation in accuracy of distortion compensation by the distortion compensating unit 20 to be inhibited. As the attenuation of the attenuator 36 disposed on the wiring 39 is increased, the attenuation of the power of the interference signal is increased. However, if the attenuation of the attenuator 36 is increased too much, the feedback signal as a distortion compensation target is decreased. Thus, the attenuation of the attenuator 36 in each branch is preferably an attenuation corresponding to a power difference between the power of the interference signal present on the wiring 39 in the branch and the noise floor Pₙ.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A base station comprising:
a memory;
a processor coupled to the memory and the processor configured to generate a distortion-compensated transmission signal; and
a plurality of transmitters, a transmitter of the plurality of transmitters configured to include
a first amplifier configured to amplify the distortion-compensated transmission signal so as to transmit the distortion-compensated transmission signal, and
an attenuator configured to attenuate a feedback signal generated by splitting the distortion-compensated transmission signal amplified by the first amplifier so as to feed back the feedback signal to the processor,
wherein the processor is further configured to perform distortion compensation according to a distortion compensation coefficient based on a power of the feedback signal.

2. The base station according to claim 1,
wherein the processor is further configured to calculate the distortion compensation coefficient based on the power of the feedback signal.

3. The base station according to claim 1, further comprising:
a second amplifier configured to amplify a power of the feedback signal according to an amount of an attenuation of the attenuator,
wherein the processor is further configured to perform the distortion compensation according to the distortion compensation coefficient based on the power of the feedback signal amplified by the second amplifier.

4. The base station according to claim 2, further comprising:
a selection circuit configured to select one of feedback signals generated in the plurality of transmitters; and
a second amplifier configured to amplify a power of a feedback signal selected by the selection circuit according to an amount of an attenuation of the attenuator,
wherein the processor is configured to calculate the distortion compensation coefficient of a transmitter that generates a feedback signal selected by the selection circuit, based on the power of the feedback signal amplified by the second amplifier.

5. The base station according to claim 1,
wherein the processor is further configured to
measure a power of an interference signal in another transmitter of the plurality of transmitters, the interference signal occurring by transmitting the feedback signal in another transmitter of the plurality of transmitters, and
control the attenuator to attenuate a power of the feedback signal so that the power of the interference signal is equal to or smaller than a predetermined power.

6. The base station according to claim 1,
wherein the processor is further configured to control the attenuator to change a power of the feedback signal according to a power of the distortion-compensated transmission signal generated.

7. The base station according to claim 2,
wherein the processor is further configured to
sequentially select, one by one, feedback signals attenuated by attenuators included in the plurality of transmitters,
set a first amount of an attenuation into the selected attenuator,
set a second amount of the attenuation larger than the first amount into the attenuator other than the selected attenuator, and
calculate the distortion compensation coefficient based on the power of the feedback signal attenuated by the attenuator into which the first amount of the attenuation is set.

8. The base station according to claim 7,
wherein the processor is configured to
select a feedback signal of the feedback signals, attenuated by the attenuator into which the first amount of the attenuation is set,
calculate the distortion compensation coefficient in common for the plurality of transmitters, based on the power of the selected feedback signal.

9. A distortion compensation method comprising:
generating a distortion-compensated transmission signal, by a processor;
amplifying the distortion-compensated transmission signal, by an amplifier;
attenuating a feedback signal generated by splitting the distortion-compensated transmission signal amplified by the amplifier, by a attenuator; and
performing distortion compensation for the distortion-compensated transmission signal according to a distortion compensation coefficient based on a power of the feedback signal, by the processor.
